(19) United States
(12) Patent Application Publication
(10) Pub. No.: US 2026/0344272 A1
(43) Pub. Date: Oct. 29, 2026

(54) DISPLAY APPARATUS

(71) Applicant: LG Display Co., Ltd., Seoul (KR)

(72) Inventors: Seongsoo CHO, Paju-si (KR); Woosung KIM, Paju-si (KR); Hyunseok NA, Paju-si (KR); Sanghak SHIN, Paju-si (KR)

(73) Assignee: LG Display Co., Ltd., Seoul (KR)

(21) Appl. No.: 19/548,949

(22) Filed: Feb. 24, 2026

(30) Foreign Application Priority Data
Apr. 23, 2025 (KR) 10-2025-0053115

(51) Int. Cl. H10K 59/80; H10K 59/122; H10K 59/35

(52) U.S. Cl. CPC H10K 59/8792; H10K 59/122; H10K 59/35

(57) ABSTRACT

A display apparatus includes a substrate having a first unit area and a second unit area disposed adjacent to each other, a plurality of pixels disposed across the first unit area and the second unit area on the substrate, and a black matrix disposed above the plurality of pixels. Each of the first unit area and the second unit area may include a first pattern area, and a second pattern area disposed between the first pattern area and a boundary between the first unit area and the second unit area. The black matrix may define a first opening pattern and a second opening pattern which expose each of the plurality of pixels and have different sizes. The first opening pattern may be disposed in the first pattern area, and the first opening pattern and the second opening pattern may be disposed in the second pattern area.

### CROSS REFERENCE TO RELATED APPLICATION

The present application claims priority to Korean Patent Application No. 10-2025-0053115, filed Apr. 23, 2025, the entire contents of which are incorporated herein for all purposes by this reference.

### TECHNICAL FIELD

The present specification relates to a display apparatus.

### BACKGROUND ART

As the information society develops, various demands for display apparatuses for displaying images are increasing, and various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle and a higher contrast ratio, and can be lighter and thinner and has lower power consumption than the LCD apparatus because it does not require a separate backlight. In addition, there is an advantage in that the OLED display apparatus can drive at a low voltage, have a fast response time, and especially have the inexpensive manufacturing cost.

However, since the OLED display apparatus using organic materials is prone to defective pixels, such as oxidation between an organic light-emitting layer and electrodes due to moisture and oxygen penetration, various technical configurations are required or implemented to minimize or reduce such penetration.

To solve the above problems, research and development have recently been directed to display apparatuses that use light-emitting diodes (LEDs) using inorganic materials as light-emitting elements, and these light-emitting display apparatuses are attracting attention as next-generation display apparatuses because they have high image quality and high reliability.

### SUMMARY

The present specification is directed to providing a display apparatus in which mura at boundaries between transfer areas is reduced.

The present specification is also directed to providing a display apparatus in which color differences at boundaries between transfer areas are reduced.

The present specification is also directed to providing a display apparatus with improved luminance and efficiency.

Objects of the present specification are not limited to the above objects, and other technical objects may be inferred from the following example embodiments.

According to one or more example embodiments of the present specification, a display apparatus includes a substrate having a first unit area and a second unit area disposed adjacent to each other, a plurality of pixels disposed across the first unit area and the second unit area on the substrate, and a black matrix disposed above the plurality of pixels, wherein each of the first unit area and the second unit area includes a first pattern area, and a second pattern area disposed between the first pattern area and a boundary between the first unit area and the second unit area, the black matrix defines a first opening pattern and a second opening pattern which expose each of the plurality of pixels and have different sizes, and the first opening pattern is disposed in the first pattern area, and the first opening pattern and the second opening pattern are disposed in the second pattern area.

According to another example embodiment of the present specification, a display apparatus includes a substrate having a first unit area and a second unit area disposed adjacent to each other, a plurality of pixels disposed across the first unit area and the second unit area on the substrate, and a black matrix disposed above the plurality of pixels, wherein each of the first unit area and the second unit area includes a first pattern area, which is a single opening pattern area, and a second pattern area, which is a mixed opening pattern area, the black matrix defines a first opening pattern and a second opening pattern which expose each of the plurality of pixels and have different sizes, and the first opening pattern is disposed in the first pattern area, and the first opening pattern and the second opening pattern are disposed in the second pattern area.

Detailed matters of other example embodiments are included in the detailed description and accompanying drawings.

According to various example embodiments of the present specification, a display apparatus with reduced boundary staining between transfer areas can be provided.

According to various example embodiments of the present specification, it is possible to reduce the color differences at the boundary between the transfer areas.

According to various example embodiments of the present specification, it is possible to improve luminance and efficiency.

According to various example embodiments of the present specification, since the luminance and efficiency of the display apparatus are improved, the low power consumption of the display apparatus can be achieved, thereby reducing energy consumption.

However, effects obtainable from the present specification are not limited to the above effects, and other effects that are not described can be clearly understood by those skilled in the art to which the present specification pertains based on the following description.

### BRIEF DESCRIPTION OF THE DRAWINGS

The accompanying drawings, which are included to provide a further understanding of the present specification and are incorporated in and constitute a part of this application, illustrate example embodiments of the present specification and together with the description serve to explain various principles of the specification.

FIG. 1 is a plan view of a display apparatus according to an example embodiment.

FIG. 2 is a plan view of the display apparatus in which a black matrix is disposed according to an example embodiment.

FIG. 3 is an enlarged view of area Q1 in FIG. 2.

FIG. 4 is an enlarged view of a mixed opening pattern area of FIG. 3.

FIG. 5 is an enlarged view of area Q2 in FIG. 2.

FIG. 6 is an enlarged view of a mixed opening pattern area of FIG. 5.

FIG. 7 is a cross-sectional view of a display apparatus according to an example embodiment.

FIG. 8 is a plan view of a display apparatus according to another example embodiment.

### DETAILED DESCRIPTION

Hereinafter, various example embodiments will be described with reference to the accompanying drawings. In the specification, where a certain component (or an area, a layer, a portion, etc.) is described as being “on,” “connected to,” or “coupled to” another component, it means that the certain component may be directly connected/coupled to another component or still another component may be disposed therebetween.

The same reference numerals indicate the same components. In addition, in the drawings, thicknesses, proportions, and dimensions of components may be exaggerated for effective description of technical contents. The term “and/or” includes all of one or more combinations that may be defined by the associated configurations.

Such terms as “first,” “second,” and the like may be used to describe various components, but the components are not limited by the terms. The terms are used only for the purpose of referring to one component separately from another. For example, a first component may be referred to as a second component, and similarly, the second component may also be referred to as the first component without departing from the scopes of various embodiments. The singular includes the plural, and vice versa, unless the context clearly dictates otherwise.

Such terms as “under,” “at a lower side,” “above,” and “at an upper side” may be used to describe the relationship between the components illustrated in the drawings. The terms are relative concepts and are described with respect to directions marked in the drawings.

It should be understood that such terms as “includes” or “has” are intended to specify the presence of features, numbers, steps, operations, components, parts, or a combination thereof described in the specification and do not preclude the presence or addition possibility of one or more other features, numbers, steps, operations, components, parts, or combinations thereof in advance.

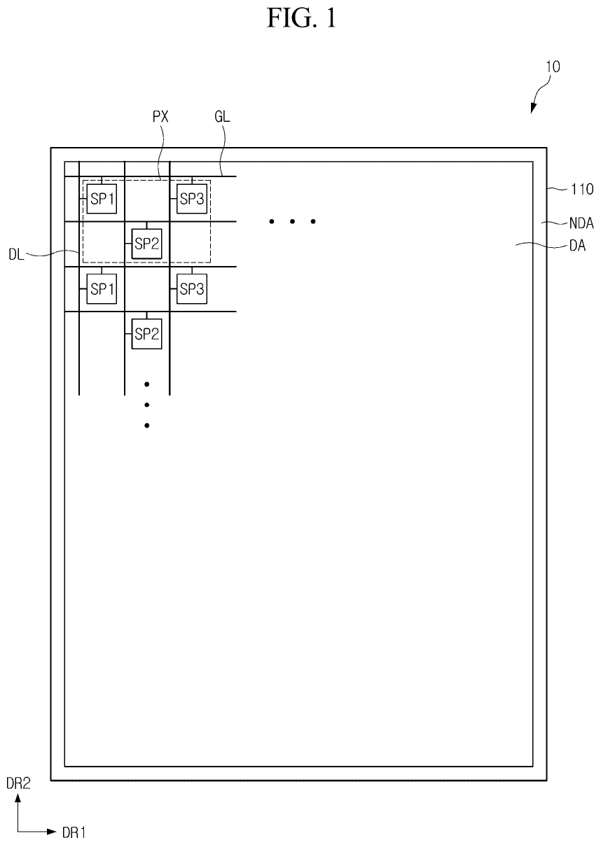

FIG. 1 is a plan view of a display apparatus according to an example embodiment.

As shown in FIG. 1, a display apparatus 10 according to an example embodiment of the present specification may be applied to a TV, a signage, a mobile terminal such as a cell phone or smart phone, a computer display such as a laptop or desktop, a head-up display (HUD) for a vehicle, a display backlight unit, a virtual reality (VR), augmented reality (AR), or mixed reality (MR) display, etc. However, the configuration according to the example embodiment described herein may be applied to any display-capable apparatus in the same manner even when a new product type is developed in the future.

The display apparatus 10 may use a micro light-emitting diode (LED) as a display (light-emitting) element, but is not limited thereto.

The display apparatus 10 may include a flexible display manufactured on a thin, flexible substrate. A flexible display may maintain the characteristics of a conventional flat panel display and may be bent or rolled like paper.

The display apparatus 10 may include a display area DA in which a plurality of pixels PX are disposed, and a non-display area NDA. The display area DA and the non-display area NDA may be defined on a substrate 110, but are not limited thereto.

The display area DA may display images, videos, pictures, etc., and include a plurality of pixels PX. The non-display area NDA does not display a screen and may also be referred to as a bezel area. The non-display area NDA may be disposed around the display area DA, but is not limited thereto. The non-display area NDA may be disposed to surround the display area DA, but is not limited thereto.

The non-display area NDA may be defined as an area on the substrate 110 excluding the display area DA and may have a relatively narrow width (or size) compared to the display area DA, but is not limited thereto.

The pixel PX may be composed of a plurality of sub-pixels SP1, SP2, and SP3, and the plurality of sub-pixels SP1, SP2, and SP3 may emit light of different colors. For example, the sub-pixels SP1, SP2, and SP3 may emit red, blue, and green light, respectively. However, various embodiments of the present specification are not limited thereto, and the pixel PX may also include sub-pixels that emit light of white, etc.

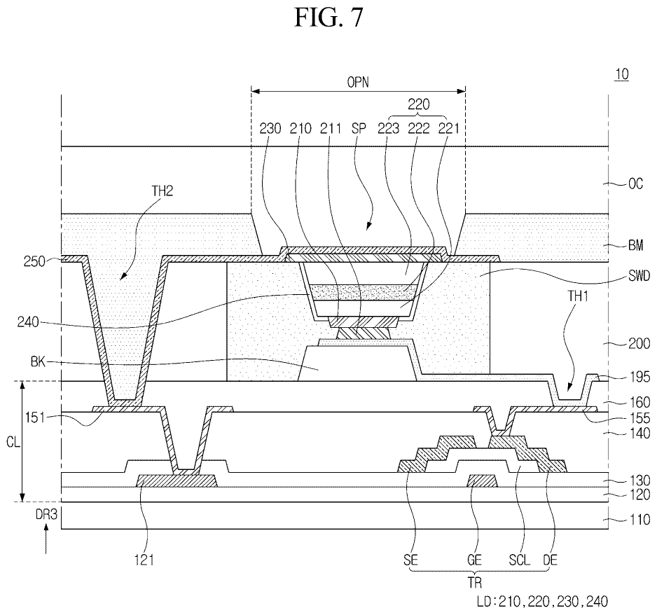

Each of the sub-pixels SP1, SP2, and SP3 may include a light-emitting element LD (see FIG. 7) that emits light, a transistor TR (see FIG. 7) that drives the light-emitting element LD (see FIG. 7), connection lines electrically connecting the light-emitting element LD to the transistor TR, and lines that transmit signals for driving each light-emitting element LD (see FIG. 7).

The sub-pixels SP1, SP2, and SP3 may be sequentially disposed in a first direction DR1.

The pixel PX may be repeatedly disposed in the first direction DR1 and a second direction DR2. Specifically, each of the sub-pixels SP1, SP2, and SP3 may be alternately disposed in the first direction DR1. Each of the sub-pixels SP1, SP2, and SP3 may be repeatedly disposed in the second direction DR2.

The display apparatus 10 may further include a gate line GL and a data line DL that are electrically connected to the sub-pixels SP1, SP2, and SP3 of each pixel PX. The gate line GL and the data line DL may provide various signals to the sub-pixels SP1, SP2, and SP3 of each pixel PX.

The gate line GL may extend in the first direction DR1 and may be repeatedly disposed in the second direction DR2. The data line DL may extend in the second direction DR2 and may be repeatedly disposed in the first direction DR1. The gate line GL and the data line DL may intersect each other.

The display apparatus 10 may include the substrate 110 that provides a space in which the plurality of pixels PX may be disposed. The substrate 110 is an array substrate on which transistors are formed and may be made of a plastic material or glass material.

In one example, the substrate 110 may include an opaque or colored polyimide material. In this case, the display apparatus 10 may further include a back plate coupled to a rear surface of the substrate 110 to maintain the substrate 110 in a flat surface state.

In one example, the back plate may include a plastic material, for example, a polyethylene terephthalate material.

In one example, the substrate 110 may be a glass substrate. For example, the glass substrate 110 may be a thin glass substrate having a thickness of 100 μm or less and may have flexible properties.

In addition, the substrate 110 may be formed by bonding two or more substrates or being divided into two or more layers.

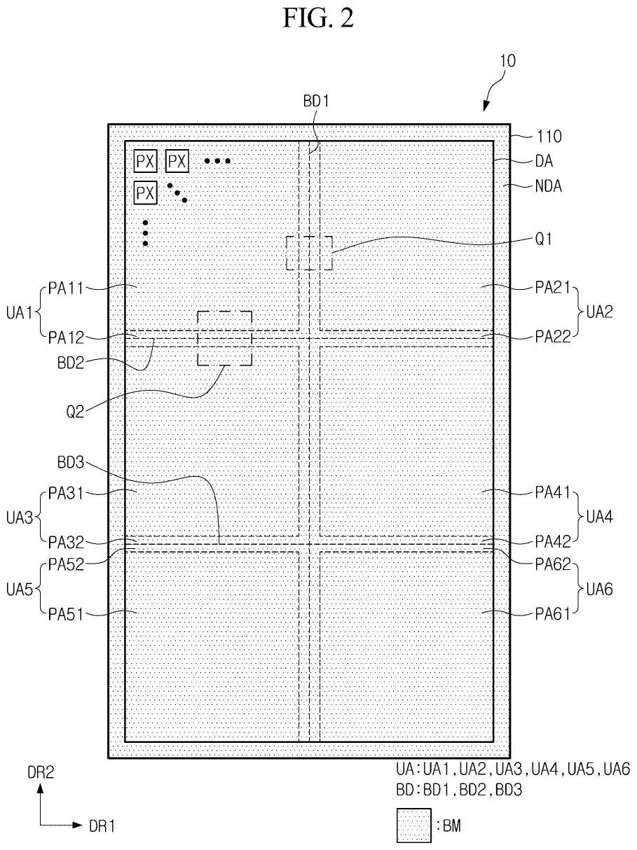

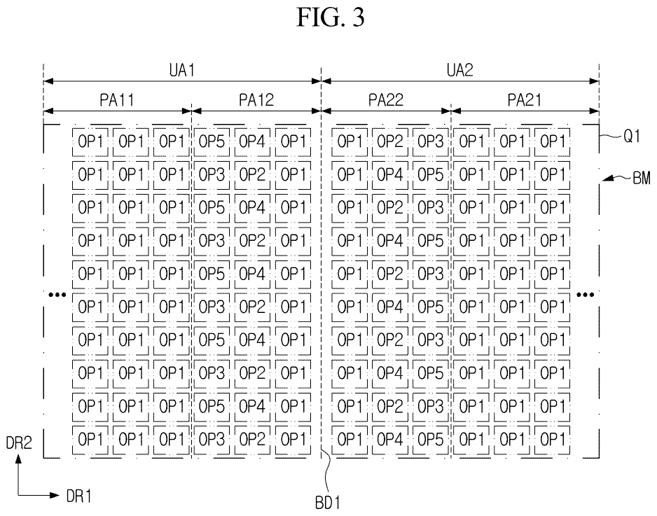

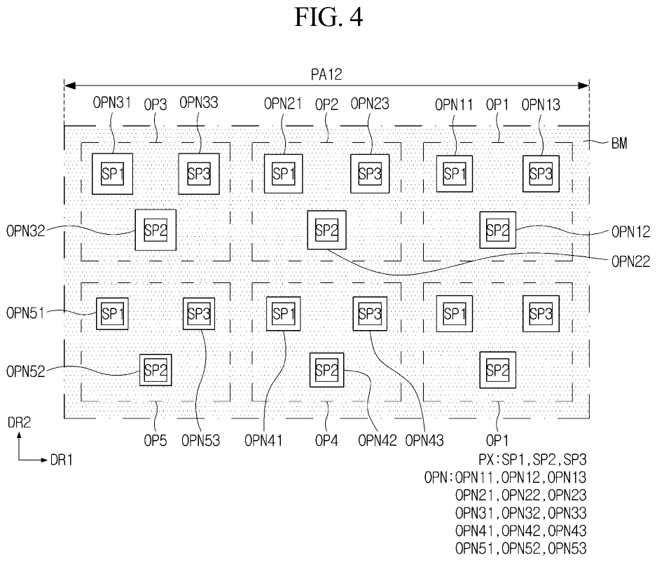

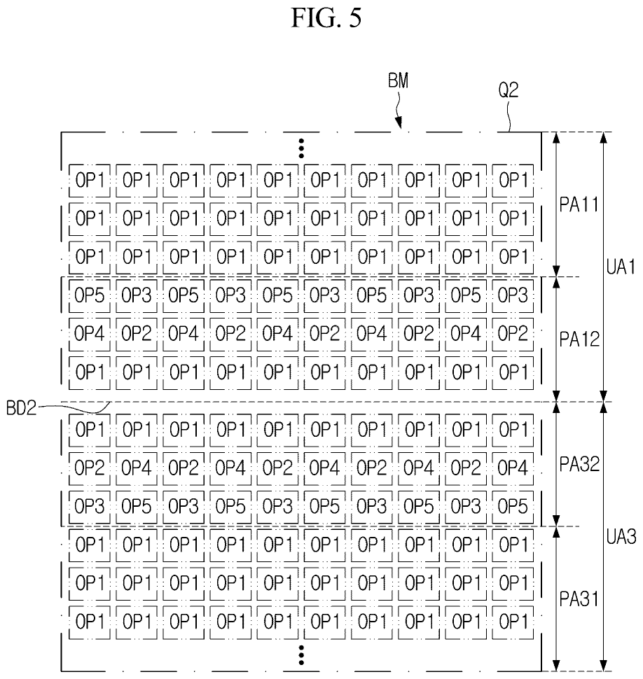

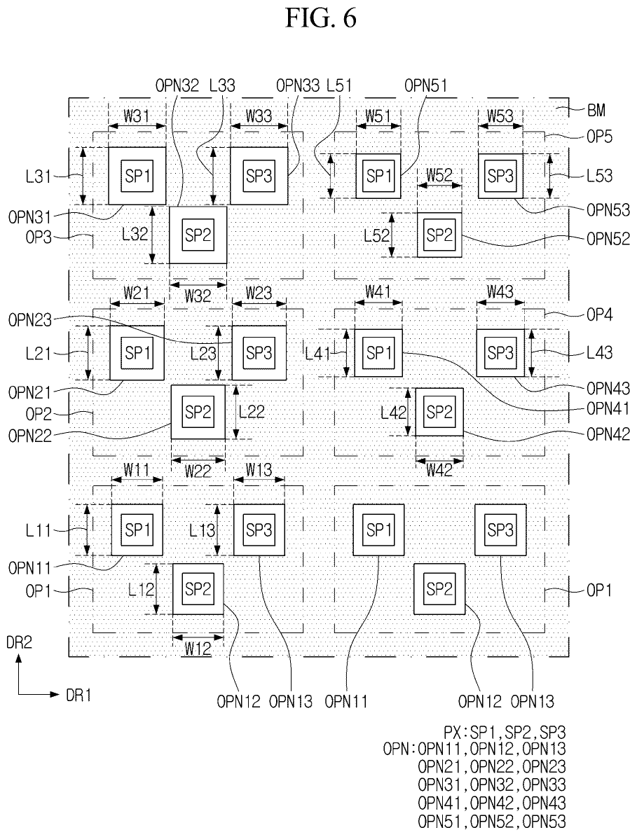

FIG. 2 is a plan view of the display apparatus in which a black matrix is disposed according to an example embodiment. FIG. 3 is an enlarged view of area Q1 in FIG. 2. FIG. 4 is an enlarged view of a mixed opening pattern area of FIG. 3. FIG. 5 is an enlarged view of area Q2 in FIG. 2. FIG. 6 is an enlarged view of a mixed opening pattern area of FIG. 5.

FIGS. 3 and 5 illustrate example arrangements of opening patterns OP1, OP2, OP3, OP4, and OP5 defined by a black matrix BM.

As shown in FIGS. 2 to 6, the display area DA may include a plurality of unit areas UA (UA1, UA2, UA3, UA4, UA5, UA6). A boundary BD may be disposed between the unit areas UA1, UA2, UA3, UA4, UA5, and UA6. The boundary BD may include first to third boundaries BD1, BD2, and BD3. That is, the display area DA may be divided into the plurality of unit areas UA (UA1, UA2, UA3, UA4, UA5, UA6) by the boundaries BD (BD1, BD2, BD3).

Here, the boundaries BD (BD1, BD2, BD3) may be virtual lines disposed between the unit areas (UA1, UA2, UA3, UA4, UA5, UA6).

When micro LEDs are used as light-emitting elements, each of the unit areas UA1, UA2, UA3, UA4, UA5, and UA6 may correspond to a single area into which a plurality of micro LEDs are collectively transferred through separate stamping processes.

As illustrated in FIG. 2, when the display apparatus 10 includes six unit areas UA1, UA2, UA3, UA4, UA5, and UA6, the plurality of micro LEDs may be transferred through six stamping processes. The plurality of micro LEDs may be transferred to each of the unit areas UA1, UA2, UA3, UA4, UA5, and UA6 through each stamping process.

The display apparatus 10 may further include the black matrix BM. The black matrix BM may be disposed across the display area DA and the non-display area NDA, but is not limited thereto.

The black matrix BM may be disposed on the pixel PX and may expose a light-emitting area of the pixel PX. That is, the black matrix BM may expose the light-emitting area of each of the sub-pixels SP1, SP2, and SP3.

The black matrix BM may include a plurality of opening patterns OP (OP1, OP2, OP3, OP4, OP5). Each of the opening patterns OP (OP1, OP2, OP3, OP4, OP5) may be disposed to correspond to each pixel PX. Each of the opening patterns OP (OP1, OP2, OP3, OP4, OP5) may expose the light-emitting area of each pixel PX.

Each of the opening patterns OP1, OP2, OP3, OP4, and OP5 may include an opening OPN corresponding to each of the sub-pixels SP1, SP2, and SP3. The openings OPN corresponding one-to-one to the sub-pixels SP1, SP2, and SP3 may be separated from each other. Each opening OPN may expose the light-emitting area of each of the sub-pixels SP1, SP2, and SP3 of each pixel PX.

In the present specification, when the opening pattern OP and the opening OPN defined by the black matrix BM expose the pixel PX or the sub-pixels SP1, SP2, and SP3, it may mean that the light-emitting area of the pixel PX or the light-emitting area of each of the sub-pixels SP1, SP2, and SP3 is exposed.

Each opening OPN may be defined by passing through the black matrix BM in a thickness direction.

Each opening OPN may have a closed curve shape in plan view, but is not limited thereto, and the planar shape of each opening OPN may be diverse.

The opening patterns OP (OP1, OP2, OP3, OP4, OP5) may include first openings OPN11, OPN21, OPN31, OPN41, and OPN51 corresponding to a first sub-pixel SP1, second openings OPN12, OPN22, OPN32, OPN42, and OPN52 corresponding to a second sub-pixel SP2, and third openings OPN13, OPN23, OPN33, OPN43, and OPN53 corresponding to a third sub-pixel SP3, respectively.

A first opening pattern OP1 may include an 11th opening OPN11 corresponding to the first sub-pixel SP1, a 12th opening OPN12 corresponding to the second sub-pixel SP2, and a 13th opening OPN13 corresponding to the third sub-pixel SP3.

Here, the 11th opening OPN11 may correspond to the first opening, the 12th opening OPN12 may correspond to the second opening, and the 13th opening OPN13 may correspond to the third opening.

When the first sub-pixel SP1 emits red light, the second sub-pixel SP2 emits green light, and the third sub-pixel SP3 emits blue light, the 11th opening OPN11 and the 12th opening OPN12 are formed to have the same planar size (area), and the 13th opening OPN13 may be formed to have a planar size smaller than those of the 11th opening OPN11 and the 12th opening OPN12, but is not limited thereto.

A second opening pattern OP2 may include a 21st opening OPN21 corresponding to the first sub-pixel SP1, a 22nd opening OPN22 corresponding to the second sub-pixel SP2, and a 23rd opening OPN23 corresponding to the third sub-pixel SP3.

Here, the 21st opening OPN21 may correspond to the first opening, the 22nd opening OPN22 may correspond to the second opening, and the 23rd opening OPN23 may correspond to the third opening.

When the first sub-pixel SP1 emits red light, the second sub-pixel SP2 emits green light, and the third sub-pixel SP3 emits blue light, the 21st opening OPN21 and the 22nd opening OPN22 are formed to have the same planar size (area), and the 23rd opening OPN23 may be formed to have a planar size smaller than those of the 21st opening OPN21 and the 22nd opening OPN22, but is not limited thereto.

A third opening pattern OP3 may include a 31st opening OPN31 corresponding to the first sub-pixel SP1, a 32nd opening OPN32 corresponding to the second sub-pixel SP2, and a 33rd opening OPN33 corresponding to the third sub-pixel SP3.

Here, the 31st opening OPN31 may correspond to the first opening, the 32nd opening OPN32 may correspond to the second opening, and the 33rd opening OPN33 may correspond to the third opening.

When the first sub-pixel SP1 emits red light, the second sub-pixel SP2 emits green light, and the third sub-pixel SP3 emits blue light, the 31st opening OPN31 and the 32nd opening OPN32 are formed to have the same planar size (area), and the 33rd opening OPN33 may be formed to have a planar size smaller than those of the 31st opening OPN31 and the 32nd opening OPN32, but is not limited thereto.

A fourth opening pattern OP4 may include a 41st opening OPN41 corresponding to the first sub-pixel SP1, a 42nd opening OPN42 corresponding to the second sub-pixel SP2, and a 43rd opening OPN43 corresponding to the third sub-pixel SP3.

Here, the 41st opening OPN41 may correspond to the first opening, the 42nd opening OPN42 may correspond to the second opening, and the 43rd opening OPN43 may correspond to the third opening.

When the first sub-pixel SP1 emits red light, the second sub-pixel SP2 emits green light, and the third sub-pixel SP3 emits blue light, the 41st opening OPN41 and the 42nd opening OPN42 are formed to have the same planar size (area), and the 43rd opening OPN43 may be formed to have a planar size smaller than those of the 41st opening OPN41 and the 42nd opening OPN42, but is not limited thereto.

A fifth opening pattern OP5 may include a 51st opening OPN51 corresponding to the first sub-pixel SP1, a 52nd opening OPN52 corresponding to the second sub-pixel SP2, and a 53rd opening OPN53 corresponding to the third sub-pixel SP3.

Here, the 51st opening OPN51 may correspond to the first opening, the 52nd opening OPN52 may correspond to the second opening, and the 53rd opening OPN53 may correspond to the third opening.

When the first sub-pixel SP1 emits red light, the second sub-pixel SP2 emits green light, and the third sub-pixel SP3 emits blue light, the 51st opening OPN51 and the 52nd opening OPN52 are formed to have the same planar size (area), and the 53rd opening OPN53 may be formed to have a planar size smaller than those of the 51st opening OPN51 and the 52nd opening OPN52, but is not limited thereto.

The opening patterns OP1, OP2, OP3, OP4, and OP5 may have different sizes. Here, when the opening patterns OP (OP1, OP2, OP3, OP4, OP5) have different sizes, it may mean that the planar sizes (areas) of the openings OPN corresponding to the same sub-pixels SP1, SP2, and SP3 in the opening patterns OP (OP1, OP2, OP3, OP4, OP5) have different sizes.

For example, the second opening pattern OP2 may have a larger size than the first opening pattern OP1.

In this case, the planar size of the 21st opening OPN21 may be larger than that of the 11th opening OPN11, the planar size of the 22nd opening OPN22 may be larger than that of the 12th opening OPN12, and the planar size of the 23rd opening OPN23 may be larger than that of the 13th opening OPN13.

The third opening pattern OP3 may have a larger size than the second opening pattern OP2.

In this case, the planar size of the 31st opening OPN31 may be larger than that of the 21st opening OPN21, the planar size of the 32nd opening OPN32 may be larger than that of the 22nd opening OPN22, and the planar size of the 33rd opening OPN33 may be larger than that of the 23rd opening OPN23.

The fourth opening pattern OP4 may have a smaller size than the first opening pattern OP1.

In this case, the planar size of the 41st opening OPN41 may be smaller than that of the 11th opening OPN11, the planar size of the 42nd opening OPN42 may be smaller than that of the 12th opening OPN12, and the planar size of the 43rd opening OPN43 may be smaller than that of the 13th opening OPN13.

The fifth opening pattern OP5 may have a smaller size than the fourth opening pattern OP4.

In this case, the planar size of the 51st opening OPN51 may be smaller than that of the 41st opening OPN41, the planar size of the 52nd opening OPN52 may be smaller than that of the 42nd opening OPN42, and the planar size of the 53rd opening OPN53 may be smaller than that of the 43rd opening OPN43.

For example, in the first opening pattern OP1, the 11th opening OPN11 and the 12th opening OPN12 may have lengths W11 and W12 of 16 micrometers (10⁻⁶ meters) in the first direction DR1 and have lengths L11 and L12 of 16 micrometers in the second direction DR2. The 13th opening OPN13 may have a length W13 of 14 micrometers in the first direction DR1 and a length L13 of 14 micrometers in the second direction DR2.

In the second opening pattern OP2, the 21st opening OPN21 and the 22nd opening OPN22 may have lengths W21 and W22 of 18 micrometers in the first direction DR1 and have lengths L21 and L22 of 18 micrometers in the second direction DR2. The 23rd opening OPN23 may have a length W23 of 16 micrometers in the first direction DR1 and a length L23 of 16 micrometers in the second direction DR2.

In the third opening pattern OP3, the 31st opening OPN31 and the 32nd opening OPN32 may have lengths W31 and W32 of 20 micrometers in the first direction DR1 and have lengths L31 and L32 of 20 micrometers in the second direction DR2. The 33rd opening OPN33 may have a length W33 of 18 micrometers in the first direction DR1 and a length L33 of 18 micrometers in the second direction DR2.

In the fourth opening pattern OP4, the 41st opening OPN41 and the 42nd opening OPN42 may have lengths W41 and W42 of 14 micrometers in the first direction DR1 and have lengths L41 and L42 of 14 micrometers in the second direction DR2. The 43rd opening OPN43 may have a length W43 of 12 micrometers in the first direction DR1 and a length L43 of 12 micrometers in the second direction DR2.

In the fifth opening pattern OP5, the 51st opening OPN51 and the 52nd opening OPN52 may have lengths W51 and W52 of 12 micrometers in the first direction DR1 and have lengths L51 and L52 of 12 micrometers in the second direction DR2. The 53rd opening OPN53 may have a length W53 of 10 micrometers in the first direction DR1 and a length L53 of 10 micrometers in the second direction DR2.

The unit areas UA1, UA2, UA3, UA4, UA5, and UA6 may include first pattern areas PA11, PA21, PA31, PA41, PA51, and PA61, which are single opening pattern areas, and second pattern areas PA12, PA22, PA32, PA42, PA52, and PA62, which are mixed opening pattern areas, respectively.

In each of the first pattern areas PA11, PA21, PA31, PA41, PA51, and PA61, which are single opening pattern areas, the first opening pattern OP1 may be disposed. In each of the first pattern areas PA11, PA21, PA31, PA41, PA51, and PA61, which are single opening pattern areas, only the first opening pattern OP1 may be disposed.

In each of the second pattern areas PA12, PA22, PA32, PA42, PA52, and PA62, which are mixed opening pattern areas, at least two of the first to fifth opening patterns OP1, OP2, OP3, OP4, and OP5 may be disposed. In the present specification, all of the first to fifth opening patterns OP1, OP2, OP3, OP4, and OP5 are described as being disposed in each of the second pattern areas PA12, PA22, PA32, PA42, PA52, and PA62, which are mixed opening pattern areas, but various embodiments of the present specification are not limited thereto.

A first unit area UA1 may include an 11th pattern area PA11 corresponding to the first pattern area, which is a single opening pattern area, and a 12th pattern area PA12 corresponding to the second pattern area, which is a mixed opening pattern area.

A second unit area UA2 may include a 21st pattern area PA21 corresponding to the first pattern area, which is a single opening pattern area, and a 22nd pattern area PA22 corresponding to the second pattern area, which is a mixed opening pattern area.

A third unit area UA3 may include a 31st pattern area PA31 corresponding to the first pattern area, which is a single opening pattern area, and a 32nd pattern area PA32 corresponding to the second pattern area, which is a mixed opening pattern area.

A fourth unit area UA4 may include a 41st pattern area PA41 corresponding to the first pattern area, which is a single opening pattern area, and a 42nd pattern area PA42 corresponding to the second pattern area, which is a mixed opening pattern area.

A fifth unit area UA5 may include a 51st pattern area PA51 corresponding to the first pattern area, which is a single opening pattern area, and a 52nd pattern area PA52 corresponding to the second pattern area, which is a mixed opening pattern area.

A sixth unit area UA6 may include a 61st pattern area PA61 corresponding to the first pattern area, which is a single opening pattern area, and a 62nd pattern area PA62 corresponding to the second pattern area, which is a mixed opening pattern area.

In each of the unit areas UA1, UA2, UA3, UA4, UA5, and UA6, the second pattern area may extend in a direction in which the adjacent boundary BD extends and may be disposed between the adjacent boundary BD and the first pattern area.

For example, in the first unit area UA1, the 12th pattern area PA12 may extend in the second direction DR2 around the first boundary BD1 extending in the second direction DR2 and may be disposed between the 11th pattern area PA11 and the first boundary BD1. In addition, in the first unit area UA1, the 12th pattern area PA12 may extend in the first direction DR1 around the second boundary BD2 extending in the first direction DR1 and may be disposed between the 11th pattern area PA11 and the second boundary BD2.

The description of the arrangement of the 11th pattern area PA11 and the 12th pattern area PA12 in the first unit area UA1 may be applied to the remaining unit areas UA2, UA3, UA4, UA5, and UA6 in substantially the same manner.

In each of the unit areas UA1, UA2, UA3, UA4, UA5, and UA6, the second to fourth opening patterns OP2, OP3, OP4, and OP5 disposed in the second pattern area may be disposed between the first opening pattern OP1 disposed in the second pattern area and the first opening pattern OP1 disposed in the first pattern area. In addition, the first opening pattern OP1 disposed in the second pattern area may be disposed between the second to fourth opening patterns OP2, OP3, OP4, and OP5 disposed in the second pattern area and the adjacent boundaries BD.

For example, in the first unit area UA1, the second to fourth opening patterns OP2, OP3, OP4, and OP5 disposed in the 12th pattern area PA12 may be disposed between the first opening pattern OP1 disposed in the 12th pattern area PA12 and the first opening pattern OP1 disposed in the 11th pattern area PA11. In addition, the first opening pattern OP1 disposed in the 12th pattern area PA12 may be disposed between the second to fourth opening patterns OP2, OP3, OP4, and OP5 disposed in the 12th pattern area PA12 and the adjacent first boundary BD1.

In the second pattern area of each of the unit areas UA1, UA2, UA3, UA4, UA5, and UA6, the first opening patterns OP1 may be repeatedly disposed in an extension direction of the adjacent boundary BD. The second opening pattern OP2 may be disposed between the first opening pattern OP1 and the third opening pattern OP3, and the fourth opening pattern OP4 may be disposed between the first opening pattern OP1 and the fifth opening pattern OP5.

In the first unit area UA1, the first opening pattern OP1, the second opening pattern OP2, and the third opening pattern OP3 may be disposed side by side in the first direction DR1 around the first boundary BD1 extending in the second direction DR2. In the first unit area UA1, the first opening pattern OP1, the second opening pattern OP2, and the third opening pattern OP3 may be disposed side by side in the second direction DR2 around the second boundary BD2 extending in the first direction DR1.

In addition, in the second pattern area of each of the unit areas UA1, UA2, UA3, UA4, UA5, and UA6, the second opening pattern OP2 and the fourth opening pattern OP4 may be alternately and repeatedly disposed in the extension direction of the adjacent boundary BD, and the third opening pattern OP3 and the fifth opening pattern OP5 may be alternately and repeatedly disposed in the extension direction of the adjacent boundary BD.

For example, in the 12th pattern area PA12 of the first unit area UA1, the first opening pattern OP1 may be repeatedly disposed in the second direction DR2 in an area adjacent to the first boundary BD1 and may be repeatedly disposed in the first direction DR1 in an area adjacent to the second boundary BD2. The second opening pattern OP2 may be disposed between the first opening pattern OP1 and the third opening pattern OP3, and the fourth opening pattern OP4 may be disposed between the first opening pattern OP1 and the fifth opening pattern OP5.

In addition, in the 12th pattern area PA12 of the first unit area UA1, the second opening pattern OP2 and the fourth opening pattern OP4 may be alternately and repeatedly disposed in the second direction DR2 in the area adjacent to the first boundary BD1, and the second opening pattern OP2 and the fourth opening pattern OP4 may be alternately and repeatedly disposed in the first direction DR1 in the area adjacent to the second boundary BD2.

In the 12th pattern area PA12 of the first unit area UA1, the third opening pattern OP3 and the fifth opening pattern OP5 may be alternately and repeatedly disposed in the second direction DR2 in the area adjacent to the first boundary BD1, and the third opening pattern OP3 and the fifth opening pattern OP5 may be alternately and repeatedly disposed in the first direction DR1 in the area adjacent to the second boundary BD2.

The description of the arrangement relationship of each of the opening patterns OP1, OP2, OP3, OP4, and OP5 and the boundary BD in the first unit area UA1 may be applied to the remaining unit areas UA2, UA3, UA4, UA5, and UA6 in substantially the same manner.

The first opening patterns OP1 disposed in the second pattern areas of adjacent unit areas UA1, UA2, UA3, UA4, UA5, and UA6 may be disposed adjacent to each other with the boundary BD interposed therebetween.

For example, in the first unit area UA1 and the second unit area UA2 adjacent to each other, the first opening pattern OP1 disposed in the 12th pattern area PA12 and the first opening pattern OP1 disposed in the 22nd pattern area PA22 may be disposed adjacent to each other with the first boundary BD1 interposed therebetween.

The description of the arrangement relationship between the first opening pattern OP1 and the boundary BD in the first unit area UA1 and the second unit area UA2 may be applied to the remaining unit areas UA3, UA4, UA5, and UA6 in substantially the same manner.

Since the unit areas UA1, UA2, UA3, UA4, UA5, and UA6 respectively include the second pattern areas PA12, PA22, PA32, PA42, PA52, and PA62, which are mixed opening pattern areas, around the boundaries BD (BD1, BD2, and BD3), mura and color differences that may occur at the boundaries BD (BD1, BD2, and BD3) can be reduced.

Specifically, when the micro LED is used as the light-emitting element in the display apparatus 10, the micro LEDs may be transferred to each of the unit areas UA1, UA2, UA3, UA4, UA5, and UA6 through separate stamping processes.

When the micro LEDs are transferred to each of the unit areas UA1, UA2, UA3, UA4, UA5, and UA6 using different stamping processes, the micro LEDs disposed in each of the unit areas UA1, UA2, UA3, UA4, UA5, and UA6 may exhibit differences in performance and transfer positions. Accordingly, differences in light output efficiency and luminance may occur at the boundaries BD, resulting in mura and color differences at the boundaries BD.

However, even when there are differences in performance and transfer positions among the micro LEDs disposed in each of the unit areas UA1, UA2, UA3, UA4, UA5, and UA6, the second pattern areas PA12, PA22, PA32, PA42, PA52, and PA62, which are mixed opening pattern areas, are disposed around the boundaries BD (BD1, BD2, and BD3), thereby mitigating mura and color differences at the boundaries caused by these differences.

That is, by arranging the opening patterns OP1, OP2, OP3, OP4, and OP5 of different sizes around the boundaries BD, the luminance differences in light emitted from each of the sub-pixels SP1, SP2, and SP3 can be mitigated. Accordingly, the mura and color differences at the boundaries between the unit areas UA1, UA2, UA3, UA4, UA5, and UA6 can be mitigated.

The luminance and efficiency of the display apparatus 10 can be improved by reducing the mura and color differences at the boundaries. In addition, lower power consumption of the display apparatus 10 can be achieved, thereby reducing energy consumption.

Hereinafter, a cross-sectional structure of the display apparatus 10 will be described.

FIG. 7 is a cross-sectional view of a display apparatus according to an example embodiment.

FIG. 7 illustrates a cross-sectional structure of the sub-pixel SP and the periphery of the opening OPN corresponding to the sub-pixel SP. The description thereof may be applied to the peripheries of the first to third sub-pixels SP1, SP2, and SP3 (see FIG. 4) and the corresponding openings OPN (see FIG. 4).

As illustrated in FIG. 7, the display apparatus 10 may further include a circuit layer CL, the light-emitting element LD, etc., disposed between the substrate 110 and the black matrix BM. The circuit layer CL may include at least one transistor TR, a metal pattern, a connection line, etc. In addition, the display apparatus 10 may further include lines electrically connecting the transistor TR to the light-emitting element LD, and at least one insulating layer disposed between the components.

The circuit layer CL may be disposed on the substrate 110. The circuit layer CL may include a buffer layer 120, the transistor TR, a common voltage line 121, a gate insulating layer 130, a first planarization layer 140, a first connection electrode 151, a second connection electrode 155, and a second planarization layer 160. However, the configuration of the circuit layer CL is not limited thereto, and may include a larger number of connection electrodes, connection lines, inorganic insulating layers, organic insulating layers, transistors, etc.

The buffer layer 120 may be disposed on the substrate 110. The buffer layer 120 can minimize or reduce the diffusion of moisture or impurities from the substrate 110. The buffer layer 120 may be formed of silicon oxide (SiOₓ), silicon nitride (SiNₓ), etc. The buffer layer 120 may be formed of a single layer or multiple layers made of silicon oxide (SiOₓ), silicon nitride (SiNₓ), etc., but is not limited thereto.

The transistor TR may be disposed on the buffer layer 120. The transistor TR may be used as a driving element of the light-emitting element LD. The transistor TR may be a driving transistor, but is not limited thereto.

The transistor TR may be a thin-film transistor (TFT), an N-channel metal oxide semiconductor (NMOS), a P-channel metal oxide semiconductor (PMOS), a complementary metal oxide semiconductor (CMOS), a field effect transistor (FET), etc., but is not limited thereto.

The following description will be provided assuming that a plurality of transistors TR are thin-film transistors, but various embodiments of the present specification are not limited thereto.

Each of the plurality of transistors TR includes a gate electrode GE, an active layer SCL, a source electrode SE, and a drain electrode DE.

The gate electrode GE and the common voltage line 121 are disposed on the buffer layer 120. The gate electrode GE and the common voltage line 121 may be made of a conductive material, such as copper (Cu), aluminum (Al), molybdenum (Mo), titanium (Ti), or an alloy thereof, but are not limited thereto.

The common voltage line 121 may be electrically connected to a common power terminal (high-potential voltage terminal) and may receive common power to transmit the received power to a second electrode 230 of the light-emitting element LD.

The gate insulating layer 130 is disposed on the gate layer GE. The gate insulating layer 130 may insulate the gate electrode GE from the active layer SCL and may be made of an insulating material. For example, the gate insulating layer 130 may be formed of a single layer or multiple layers made of silicon oxide (SiOₓ), silicon nitride (SiNₓ), etc., but is not limited thereto.

The active layer SCL is disposed on the gate insulating layer 130. For example, the active layer SCL may be made of an oxide semiconductor, amorphous silicon, polysilicon, etc., but is not limited thereto.

A source electrode SE and a drain electrode DE are disposed to be spaced apart from each other on the active layer SCL. The source electrode SE and the drain electrode DE may be electrically connected to the active layer SCL. The source electrode SE and the drain electrode DE may be made of a conductive material, such as copper (Cu), aluminum (Al), molybdenum (Mo), titanium (Ti), or an alloy thereof, but are not limited thereto.

The first planarization layer 140 may be disposed on the transistor TR. The first planarization layer 140 may planarize an upper portion of the substrate 110 including the plurality of transistors TR.

The first planarization layer 140 may be formed of a single layer or multiple layers and may be made of an organic material. For example, the first planarization layer 140 may be made of an acrylic-based organic material, but is not limited thereto. The first planarization layer 140 includes a contact hole for electrically connecting the transistor TR to the first connection electrode 151.

Although not illustrated, a protective layer may be further disposed between the first planarization layer 140 and the transistor TR to protect underlying components.

A first connection electrode 151 and a second connection electrode 155 may be disposed on the first planarization layer 140.

The first connection electrode 151 and the second connection electrode 155 may be disposed on the same layer and made of the same material. The first connection electrode 151 and the second connection electrode 155 may be disposed on the first planarization layer 140 and made of a metallic material. For example, the first connection electrode 151 and the second connection electrode 155 may include a light-reflecting conductive material, and the light-reflecting conductive material may include at least one selected from aluminum (Al), silver (Ag), gold (Au), platinum (Pt), copper (Cu), etc.

The first connection electrode 151 may be electrically connected in contact with the common voltage line 121 through a contact hole passing through the first planarization layer 140 and the gate insulating layer 130 in the thickness direction (third direction DR3).

The second connection electrode 155 may be electrically connected in contact with the drain electrode DE of the transistor TR through a contact hole passing through the first planarization layer 140 in the thickness direction (third direction DR3).

The second planarization layer 160 may be disposed on the first connection electrode 151 and the second connection electrode 155. The second planarization layer 160 may be made of an organic material. For example, the second planarization layer 160 may be made of an acrylic-based organic material, but is not limited thereto. The second planarization layer 160 may be made of the same material as the first planarization layer 140, but is not limited thereto.

A bank pattern BK may be disposed on the second planarization layer 160. The bank pattern BK may be provided as a plurality of patterns, and each of the bank patterns BK may correspond to at least one light-emitting element LD and may be disposed below the light-emitting element LD.

The bank pattern BK may be made of an organic insulation material, such as photosensitive photo acryl or photosensitive polyimide, but is not limited thereto. The bank pattern BK may guide an attachment position of the light-emitting element in the transfer process of the light-emitting element. The bank pattern BK may be omitted.

The light-emitting element LD may be disposed on the bank pattern BK. The light-emitting element LD may be an LED or micro LED including an inorganic material as a light-emitting layer 220, but is not limited thereto. The light-emitting element LD may have a vertical structure, but is not limited thereto.

The light-emitting element LD may include a first electrode 210, the light-emitting layer 220, a second electrode 230, and a passivation film 240. The light-emitting layer 220 may include a first semiconductor layer 221, an active layer 222, and a second semiconductor layer 223. When the light-emitting element LD has a vertical structure, the first electrode 210, the first semiconductor layer 221, the active layer 222, the second semiconductor layer 223, and the second electrode 230 may overlap in the thickness direction (third direction DR3).

The first electrode 210, the light-emitting layer 220, and the second electrode 230 may be sequentially disposed in the thickness direction (third direction DR3). The first electrode 210, the light-emitting layer 220, and the second electrode 230 may overlap in the thickness direction (third direction DR3). The light-emitting layer 220 may be disposed between the first electrode 210 and the second electrode 230.

The first electrode 210 may be disposed on the light-emitting layer 220. The first electrode 210 may be an anode electrode or a cathode electrode. For example, the first electrode 210 may be an anode electrode, but is not limited thereto.

When the first electrode 210 is the anode electrode, the first electrode 210 may be electrically connected to the transistor TR. When the first electrode 210 is the anode electrode, the transistor TR and the first semiconductor layer 221 may be electrically connected through the first electrode 210.

The first electrode 210 may include a conductive material. The conductive material may be a transparent conductive material, such as indium tin oxide (ITO) or indium zinc oxide (IZO). However, various embodiments of the present specification are not limited thereto, and the conductive material may also be at least one selected from opaque conductive materials, such as nickel (Ni), gold (Au), platinum (Pt), titanium (Ti), aluminum (Al), chromium (Cr), copper (Cu), silver (Ag), or an alloy thereof.

The light-emitting layer 220 may be disposed on the first electrode 210. The first semiconductor layer 221, the active layer 222, and the second semiconductor layer 223 of the light-emitting layer 220 may be sequentially disposed in the thickness direction. The active layer 222 may be disposed between the first semiconductor layer 221 and the second semiconductor layer 223.

The first semiconductor layer 221 may be disposed on the first electrode 210. The first semiconductor layer 221 may be disposed between the first electrode 210 and the active layer 222. The first semiconductor layer 221 may include a first-type dopant. For example, the first semiconductor layer 221 may include a p-type dopant, but is not limited thereto.

When the first semiconductor layer 221 includes the p-type dopant, the first semiconductor layer 221 may supply holes to the active layer 222 and have a material, such as gallium nitride (GaN), indium aluminum phosphide (InAlP), gallium arsenide (GaAs), etc., coated with impurities, such as magnesium (Mg), zinc (Zn), beryllium (Be), etc.

The active layer 222 may be disposed on the first semiconductor layer 221. The active layer 222 may receive holes and electrons from the first semiconductor layer 221 and the second semiconductor layer 223 and emit light. The active layer 222 may be formed in a single-layer or multi-quantum well (MQW) structure and may be made of, for example, indium gallium nitride (InGaN), gallium nitride (GaN), etc., but is not limited thereto.

The second semiconductor layer 223 may be disposed on the active layer 222. The second semiconductor layer 223 may be disposed between the active layer 222 and the second electrode 230. The second semiconductor layer 223 may include a second-type dopant different from the first-type dopant. For example, the second semiconductor layer 223 may include an n-type dopant, but is not limited thereto.

When the second semiconductor layer 223 includes the n-type dopant, the second semiconductor layer 223 may supply electrons to the active layer 222 and have a material, such as gallium nitride (GaN), indium aluminum phosphide (InAlP), gallium arsenide (GaAs), etc., coated with impurities, such as silicon (Si), germanium (Ge), selenium (Se), tellurium (Te), etc.

The present specification describes the first semiconductor layer 221 including the p-type dopant and the second semiconductor layer 223 including the n-type dopant, but various embodiments of the present specification are not limited thereto, and the first semiconductor layer 221 may include the n-type dopant and the second semiconductor layer 223 may include the p-type dopant.

The light-emitting layer 220 may have a mesa structure. A side surface of the light-emitting layer 220 may be formed as an inclined surface inclined with respect to the thickness direction (third direction DR3). A planar size of the light-emitting layer 220 may increase from the first semiconductor layer 221 toward the second semiconductor layer 223. A width of the light-emitting layer 220 may increase from the first semiconductor layer 221 toward the second semiconductor layer 223.

The second electrode 230 may be disposed on the second semiconductor layer 223. The second electrode 230 may be an anode electrode or a cathode electrode. For example, when the first electrode 210 is the anode electrode, the second electrode 230 may be the cathode electrode.

The present specification describes the first electrode 210 being the anode electrode and the second electrode 230 being the cathode electrode, but various embodiments of the present specification are not limited thereto. For example, the first electrode 210 may be the cathode electrode and the second electrode 230 may be the anode electrode.

When the second electrode 230 is the cathode electrode, the second electrode 230 may be electrically connected to the common voltage line 121. When the second electrode 230 is the cathode electrode, the common voltage terminal (or the high-potential voltage terminal) and the second semiconductor layer 223 may be electrically connected through the second electrode 230 and the common voltage line 121.

The second electrode 230 may include a conductive material. The conductive material may be made of at least one selected from, for example, transparent conductive materials, such as ITO, IZO, etc., or opaque conductive materials, such as nickel (Ni), gold (Au), platinum (Pt), titanium (Ti), aluminum (Al), chromium (Cr), copper (Cu), silver (Ag), or an alloy thereof, but is not limited thereto.

The passivation film 240 may be disposed on the side surface of the light-emitting layer 220. The passivation film 240 may be disposed along the perimeter of the light-emitting layer 220 and disposed to surround the light-emitting layer 220.

The passivation film 240 may be made of an inorganic insulation material, such as silicon oxide, silicon nitride, silicon oxynitride, aluminum oxide, etc., but is not limited thereto.

The passivation film 240 can protect the light-emitting layer 220 and prevent or suppress leakage current from flowing to the side of the light-emitting layer 220.

A pixel connection electrode 195 may be disposed on the second planarization layer 160. The pixel connection electrode 195 may be made of a transparent conductive material when the display apparatus 10 is a top-emission type, or may be made of a light-reflecting conductive material when the display apparatus 10 is a bottom-emission type. The transparent conductive material may be ITO, IZO, etc., but is not limited thereto. The light-reflecting conductive material may be Al, Ag, Au, Pt, Cu, etc., but is not limited thereto. The pixel connection electrode 195 made of the light-reflecting conductive material may be formed of a single layer containing the light-reflecting conductive material or multiple layers in which single layers are stacked.

The second planarization layer 160 may define a first through-hole TH1 that passes through in the thickness direction (third direction DR3) to expose the second connection electrode 155.

Through the first through-hole TH1, one end of the pixel connection electrode 195 may be electrically connected in contact with the second connection electrode 155 exposed by the first through-hole TH1. The other end of the pixel connection electrode 195 may be disposed on the bank pattern BK, and the other end of the pixel connection electrode 195 may be electrically connected to the first electrode 210 of the light-emitting element LD.

The display apparatus 10 may further include a connection pattern 211 disposed between the pixel connection electrode 195 and the first electrode 210. The connection pattern 211 may be made of indium (In), tin (Sn), or an alloy thereof, but is not necessarily limited thereto.

The connection pattern 211 may be electrically connected in contact with the pixel connection electrode 195 and the first electrode 210. Accordingly, the first electrode 210 may be electrically connected to the other end of the pixel connection electrode 195.

An electrically conductive adhesive layer may be further disposed between the connection pattern 211 and the pixel connection electrode 195 and/or between the connection pattern 211 and the first electrode 210.

The display apparatus 10 may further include a diffusion layer SWD disposed on the second planarization layer 160. The diffusion layer SWD may be disposed around each light-emitting element LD. The diffusion layers SWD disposed around each light-emitting element LD may be separated and spaced apart from each other. An upper insulating layer 200 may be disposed between the diffusion layers SWD separated and spaced apart from each other.

The diffusion layer SWD may be selectively made of at least one of an organic compound containing TiOₓ added to Si—H—O in which a plurality of fine metal particles are dispersed and diffused, a material including a photoactive compound (PAC) and polyimide (PI), a sidewall diffuser from which TiOₓ has been removed, and an insulation material including SiOₓ and SiNₓ.

The diffusion layer SWD may reflect, refract, scatter, and diffract light emitted from the light-emitting element LD, thereby improving the light output efficiency of the light-emitting element LD.

The upper insulating layer 200 may be disposed on the pixel connection electrode 195. The upper insulating layer 200 may be disposed on the second planarization layer 160 while covering the light-emitting element LD and the pixel connection electrode 195. The upper insulating layer 200 may be disposed to surround the diffusion layer SWD disposed around each light-emitting element LD.

The present specification describes the upper insulating layer formed of a single layer, but various embodiments of the present specification are not limited thereto. For example, the upper insulating layer 200 may be formed of two or more layers.

The upper insulating layer 200 may provide a flat surface on the transistor TR and the light-emitting element LD and fix the position of the light-emitting element LD.

A common connection electrode 250 may be disposed on the upper insulating layer 200. The upper insulating layer 200 and the second planarization layer 160 may define a second through-hole TH2 that passes through in the thickness direction (third direction DR3) and exposes the first connection electrode 151.

Through the second through-hole TH2, the common connection electrode 250 may be electrically connected in contact with the first connection electrode 151 exposed by the second through-hole TH2.

The upper insulating layer 200 may define a third through-hole TH3 that passes through in the thickness direction (third direction DR3) to expose the light-emitting element LD. The third through-hole TH3 may expose the second electrode 230.

The common connection electrode 250 may be electrically connected in contact with the second electrode 230.

The common connection electrode 250 may have one end in contact with the first connection electrode 151 and the other end in contact with the second electrode 230. The second electrode 230 and the first connection electrode 151 may be electrically connected by the common connection electrode 250.

The common connection electrode 250 may be made of a transparent conductive material when the display apparatus 10 is a top-emission type, or may be made of a light-reflecting conductive material when the display apparatus 10 is a bottom-emission type. The transparent conductive material may be ITO, IZO, etc., but is not limited thereto. The light-reflecting conductive material may be Al, Ag, Au, Pt, Cu, etc., but is not limited thereto. The common connection electrode 250 made of the light-reflecting conductive material may be formed of a single layer containing the light-reflecting conductive material or multiple layers in which single layers are stacked.

The black matrix BM may be disposed on the upper insulating layer 200. The black matrix BM may be made of an organic insulation material to which black pigment is added. Color mixing between adjacent sub-pixels SP can be prevented or suppressed through the black matrix BM.

The black matrix BM may define the opening OPN that exposes the light-emitting area of the sub-pixel SP. A sidewall of the opening OPN may be disposed further inward than a side surface of the diffusion layer SWD. The side surface of the diffusion layer SWD may protrude further outward than the sidewall of the opening OPN. That is, the diffusion layer SWD may cover the entire area of the opening OPN. The diffusion layer SWD may overlap the entire area of the opening OPN in the thickness direction (third direction DR3).

An overcoat layer OC may be disposed on the black matrix BM. The overcoat layer OC may cover the black matrix BM and the common connection electrode 250. The overcoat layer OC may be made of an organic insulation material, but is not limited thereto. The overcoat layer OC may form a flat upper surface despite the presence of an underlying step.

Hereinafter, other example embodiments of the present specification will be described. For contents that are substantially the same as those described with reference to FIGS. 1 to 7 among components included in other example embodiments, the same reference numerals are given, and overlapping contents may be omitted or briefly described.

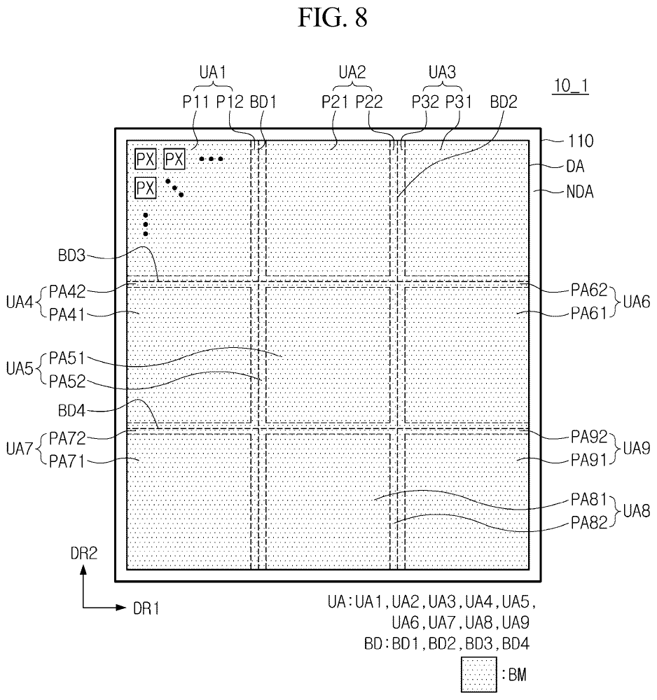

FIG. 8 is a plan view of a display apparatus according to another example embodiment.

As shown in FIG. 8, a display apparatus 10_1 according to the present example embodiment may include a unit area UA, and the unit area UA may include first to ninth unit areas UA1, UA2, UA3, UA4, UA5, UA6, UA7, UA8, and UA9.

Boundaries BD may be disposed between the unit areas UA1, UA2, UA3, UA4, UA5, UA6, UA7, UA8, and UA9. The boundary BD may include first to fourth boundaries BD1, BD2, BD3, and BD4.

When a micro LED is used as a light-emitting element, each of the unit areas UA1, UA2, UA3, UA4, UA5, UA6, UA7, UA8, and UA9 may correspond to a single area into which a plurality of micro LEDs are collectively transferred through separate stamping processes.

As illustrated in FIG. 8, when the display apparatus 10_1 includes the nine unit areas UA1, UA2, UA3, UA4, UA5, UA6, UA7, UA8, and UA9, the plurality of micro LEDs may be transferred through nine stamping processes. The plurality of micro LEDs may be transferred to each of the unit areas UA1, UA2, UA3, UA4, UA5, UA6, UA7, UA8, and UA9 through each stamping process.

The unit areas UA1, UA2, UA3, UA4, UA5, UA6, UA7, UA8, and UA9 may include first pattern areas PA11, PA21, PA31, PA41, PA51, PA61, PA71, PA81, and PA91, which are single opening pattern areas, and second pattern areas PA12, PA22, PA32, PA42, PA52, PA62, PA72, PA82, and PA92, which are mixed opening pattern areas, respectively.

In each of the first pattern areas PA11, PA21, PA31, PA41, PA51, PA61, PA71, PA81, PA91, which are single opening pattern areas, the first opening pattern OP1 may be disposed. In each of the first pattern areas PA11, PA21, PA31, PA41, PA51, PA61, PA71, PA81, and PA91, only the first opening pattern OP1 defined by the black matrix BM may be disposed.

In each of the second pattern areas PA12, PA22, PA32, PA42, PA52, PA62, PA72, PA82, PA92, which are mixed opening pattern areas, at least two of the first to fifth opening patterns OP1, OP2, OP3, OP4, and OP5 may be disposed. The present specification describes that all of the first to fifth opening patterns OP1, OP2, OP3, OP4, and OP5 defined by the black matrix BM are disposed in each of the second pattern areas PA12, PA22, PA32, PA42, PA52, PA62, PA72, PA82, and PA92, but various embodiments of the present specification are not limited thereto.

At least one of the unit areas UA1, UA2, UA3, UA4, UA5, UA6, UA7, UA8, and UA9 may be a single opening pattern area surrounded by the mixed opening pattern area.

For example, in the fifth unit area UA5, a 51st pattern area PA51, which is a single opening pattern area, may be surrounded by a 52nd pattern area PA52, which is a mixed opening pattern area.

Even in this case, that is, as the opening patterns OP1, OP2, OP3, OP4, and OP5 of different sizes are disposed around the boundaries BD, the luminance and efficiency of the display apparatus 10_1 can be improved by reducing mura and color differences at the boundaries. Furthermore, low power consumption of the display apparatus 10_1 can be achieved, thereby reducing energy consumption of the display apparatus 10_1.

A display apparatus according to various example embodiments of the present specification may be described as follows.

According to various example embodiments of the present specification, a display apparatus may include a substrate having a first unit area and a second unit area disposed adjacent to each other, a plurality of pixels disposed across the first unit area and the second unit area on the substrate, and a black matrix disposed above the plurality of pixels, in which each of the first unit area and the second unit area includes a first pattern area and a second pattern area disposed between the first pattern area and a boundary between the first unit area and the second unit area, the black matrix defines a first opening pattern and a second opening pattern which expose each of the plurality of pixels and have different sizes, the first opening pattern is disposed in the first pattern area, and the first opening pattern and the second opening pattern are disposed in the second pattern area.

According to various example embodiments of the present specification, the first unit area and the second unit area may be disposed side by side in a first direction, the boundary may extend in a second direction intersecting the first direction, and the second pattern area may extend in the second direction.

According to various example embodiments of the present specification, the second opening pattern disposed in the second pattern area may be disposed between the first opening pattern disposed in the second pattern area and the first opening pattern disposed in the first pattern area.

According to various example embodiments of the present specification, the first opening pattern disposed in the second pattern area may be repeatedly disposed in the second direction.

According to various example embodiments of the present specification, each of the plurality of pixels may include a first sub-pixel, a second sub-pixel, and a third sub-pixel which emit light of different colors, and the first opening pattern disposed in the second pattern area may include a first opening exposing the first sub-pixel, a second opening exposing the second sub-pixel, and a third opening exposing the third sub-pixel.

According to various example embodiments of the present specification, the black matrix may further define a third opening pattern having a different size from the first opening pattern and the second opening pattern, the third opening pattern may be disposed in the second pattern area, the second opening pattern may have a larger size than the first opening pattern, the third opening pattern may have a larger size than the second opening pattern, and the second opening pattern may be disposed between the first opening pattern and the third opening pattern.

According to various example embodiments of the present specification, the first opening pattern, the second opening pattern, and the third opening pattern may be disposed in a first direction, and the boundary may extend in a second direction intersecting the first direction.

According to various example embodiments of the present specification, the black matrix may further define a fourth opening pattern having a smaller size than the first opening pattern, and a fifth opening pattern having a smaller size than the fourth opening pattern, and the fourth opening pattern and the fifth opening pattern may be disposed in the second pattern area.

According to various example embodiments of the present specification, the first opening pattern may be repeatedly disposed in the second direction around the boundary, and the fourth opening pattern may be disposed between the first opening pattern and the fifth opening pattern.

According to various example embodiments of the present specification, the second opening pattern and the fourth opening pattern may be alternately and repeatedly disposed in the second direction, and the third opening pattern and the fifth opening pattern may be alternately and repeatedly disposed in the second direction.

According to various example embodiments of the present specification, the first opening pattern may be disposed between the second opening pattern and the boundary.

According to various example embodiments of the present specification, the first pattern area may be a single opening pattern area, and the second pattern area may be a mixed opening pattern area.

According to various example embodiments of the present specification, the display apparatus may further include a display area including the first unit area and the second unit area, and a non-display area disposed around the display area.

According to various example embodiments of the present specification, the display apparatus may further include a circuit layer disposed between the substrate and the black matrix, a bank disposed on the circuit layer, a light-emitting element disposed on the bank, a diffusion layer disposed to surround the light-emitting element, and a planarization layer disposed to surround the diffusion layer.

According to various example embodiments of the present specification, each of the plurality of pixels may include at least one sub-pixel, the light-emitting element may be disposed in each sub-pixel, each of the first opening pattern and the second opening pattern may include at least one opening exposing the sub-pixel, and a sidewall of the at least one opening may be disposed further inward than a side surface of the diffusion layer.

According to various example embodiments of the present specification, a display apparatus may include a substrate having a first unit area and a second unit area disposed adjacent to each other, a plurality of pixels disposed across the first unit area and the second unit area on the substrate, and a black matrix disposed above the plurality of pixels, in which each of the first unit area and the second unit area includes a first pattern area that is a single opening pattern area and a second pattern area that is a mixed opening pattern area, the black matrix defines a first opening pattern and a second opening pattern which expose each of the plurality of pixels and have different sizes, the first opening pattern is disposed in the first pattern area, and the first opening pattern and the second opening pattern are disposed in the second pattern area.

According to various example embodiments of the present specification, the second pattern area may be disposed between a boundary between the first unit area and the second unit area and the first pattern area.

According to various example embodiments of the present specification, the first unit area and the second unit area may be disposed side by side in a first direction, the boundary may extend in a second direction intersecting the first direction, and the second pattern area may extend in the second direction.

According to various example embodiments of the present specification, the second opening pattern disposed in the second pattern area may be disposed between the first opening pattern disposed in the second pattern area and the first opening pattern disposed in the first pattern area.

According to various example embodiments of the present specification, the black matrix may further define a third opening pattern having a different size from the first opening pattern and the second opening pattern, the third opening pattern may be disposed in the second pattern area, the second opening pattern may have a larger size than the first opening pattern, the third opening pattern may have a larger size than the second opening pattern, and the second opening pattern may be disposed between the first opening pattern and the third opening pattern.

According to various example embodiments of the present specification, the display apparatus may further include a circuit layer disposed between the substrate and the black matrix, a bank disposed on the circuit layer, a light-emitting element disposed on the bank, a diffusion layer disposed to surround the light-emitting element, and a planarization layer disposed to surround the diffusion layer.

According to various example embodiments of the present specification, each of the plurality of pixels may include at least one sub-pixel, the light-emitting element may be disposed in each sub-pixel, each of the first opening pattern and the second opening pattern may include at least one opening exposing the sub-pixel, and a sidewall of the at least one opening may be disposed further inward than a side surface of the diffusion layer.

Although various example embodiments have been described above with reference to the accompanying drawings, those skilled in the art to which the present specification pertains will be able to understand that the above-described technical configurations can be carried out in other specific forms without changing the technical spirit or essential features thereof. Accordingly, it should be understood that the above-described example embodiments are illustrative and not restrictive in all respects. In addition, the protected scope of various embodiments may be determined by the appended claims and their equivalents rather than detailed description. In addition, the meaning and scope of the claims and all changed or modified forms derived from the equivalent concept thereof should be construed as being included in the scope of the present specification.

### DESCRIPTION OF REFERENCE NUMERALS

10: display apparatus
110: substrate
TR: transistor
BK: bank pattern
LD: light-emitting element
210: first electrode
220: light-emitting layer
230: second electrode
240: passivation film
200: upper insulating layer
BM: black matrix
UA: unit area
PA: pattern area
OP: opening pattern
OPN: opening
BD: boundary

What is claimed is:

1. A display apparatus, comprising:
a substrate having a first unit area and a second unit area disposed adjacent to each other;
a plurality of pixels disposed across the first unit area and the second unit area on the substrate; and
a black matrix disposed above the plurality of pixels,
wherein each of the first unit area and the second unit area includes:
a first pattern area; and
a second pattern area disposed between the first pattern area and a boundary between the first unit area and the second unit area,
wherein the black matrix defines a first opening pattern and a second opening pattern which expose each of the plurality of pixels and have different sizes, and
wherein the first opening pattern is disposed in the first pattern area, and the first opening pattern and the second opening pattern are disposed in the second pattern area.

2. The display apparatus of claim 1, wherein:
the first unit area and the second unit area are disposed side by side in a first direction;
the boundary extends in a second direction intersecting the first direction; and
the second pattern area extends in the second direction.

3. The display apparatus of claim 2, wherein the second opening pattern disposed in the second pattern area is disposed between the first opening pattern disposed in the second pattern area and the first opening pattern disposed in the first pattern area.

4. The display apparatus of claim 3, wherein the first opening pattern disposed in the second pattern area is repeatedly disposed in the second direction.

5. The display apparatus of claim 4, wherein:
each of the plurality of pixels includes a first sub-pixel, a second sub-pixel, and a third sub-pixel which emit light of different colors; and
the first opening pattern disposed in the second pattern area includes a first opening exposing the first sub-pixel, a second opening exposing the second sub-pixel, and a third opening exposing the third sub-pixel.

6. The display apparatus of claim 1, wherein:
the black matrix further defines a third opening pattern having a different size from the first opening pattern and the second opening pattern;
the third opening pattern is disposed in the second pattern area;
the second opening pattern has a larger size than the first opening pattern, and the third opening pattern has a larger size than the second opening pattern; and
the second opening pattern is disposed between the first opening pattern and the third opening pattern.

7. The display apparatus of claim 6, wherein:
the first opening pattern, the second opening pattern, and the third opening pattern are disposed in a first direction; and
the boundary extends in a second direction intersecting the first direction.

8. The display apparatus of claim 7, wherein:
the black matrix further defines a fourth opening pattern having a smaller size than the first opening pattern, and a fifth opening pattern having a smaller size than the fourth opening pattern; and
the fourth opening pattern and the fifth opening pattern are disposed in the second pattern area.

9. The display apparatus of claim 8, wherein:
the first opening pattern is repeatedly disposed in the second direction around the boundary; and
the fourth opening pattern is disposed between the first opening pattern and the fifth opening pattern.

10. The display apparatus of claim 9, wherein:
the second opening pattern and the fourth opening pattern are alternately and repeatedly disposed in the second direction; and
the third opening pattern and the fifth opening pattern are alternately and repeatedly disposed in the second direction.

11. The display apparatus of claim 7, wherein the first opening pattern is disposed between the second opening pattern and the boundary.

12. The display apparatus of claim 1, wherein the first pattern area is a single opening pattern area, and the second pattern area is a mixed opening pattern area.

13. The display apparatus of claim 1, further comprising a display area including the first unit area and the second unit area, and a non-display area disposed around the display area.

14. The display apparatus of claim 1, further comprising:
a circuit layer disposed between the substrate and the black matrix;
a bank disposed on the circuit layer;
a light-emitting element disposed on the bank;
a diffusion layer disposed to surround the light-emitting element; and
a planarization layer disposed to surround the diffusion layer.

15. The display apparatus of claim 14, wherein:
each of the plurality of pixels includes at least one sub-pixel;
the light-emitting element is disposed in each sub-pixel;
each of the first opening pattern and the second opening pattern includes at least one opening exposing the sub-pixel; and
a sidewall of the at least one opening is disposed further inward than a side surface of the diffusion layer.

16. A display apparatus, comprising:
a substrate having a first unit area and a second unit area disposed adjacent to each other;
a plurality of pixels disposed across the first unit area and the second unit area on the substrate; and
a black matrix disposed above the plurality of pixels,
wherein each of the first unit area and the second unit area includes a first pattern area, which is a single opening pattern area, and a second pattern area, which is a mixed opening pattern area,
wherein the black matrix defines a first opening pattern and a second opening pattern which expose each of the plurality of pixels and have different sizes, and
wherein the first opening pattern is disposed in the first pattern area, and the first opening pattern and the second opening pattern are disposed in the second pattern area.

17. The display apparatus of claim 16, wherein the second pattern area is disposed between a boundary between the first unit area and the second unit area and the first pattern area.

18. The display apparatus of claim 17, wherein:
the first unit area and the second unit area are disposed side by side in a first direction;
the boundary extends in a second direction intersecting the first direction; and
the second pattern area extends in the second direction.

19. The display apparatus of claim 18, wherein the second opening pattern disposed in the second pattern area is disposed between the first opening pattern disposed in the second pattern area and the first opening pattern disposed in the first pattern area.

20. The display apparatus of claim 17, wherein:
the black matrix further defines a third opening pattern having a different size from the first opening pattern and the second opening pattern;
the third opening pattern is disposed in the second pattern area;
the second opening pattern has a larger size than the first opening pattern, and the third opening pattern has a larger size than the second opening pattern; and
the second opening pattern is disposed between the first opening pattern and the third opening pattern.

21. The display apparatus of claim 16, further comprising:
a circuit layer disposed between the substrate and the black matrix;
a bank disposed on the circuit layer;
a light-emitting element disposed on the bank;
a diffusion layer disposed to surround the light-emitting element; and
a planarization layer disposed to surround the diffusion layer.

22. The display apparatus of claim 21, wherein:
each of the plurality of pixels includes at least one sub-pixel;
the light-emitting element is disposed in each sub-pixel;
each of the first opening pattern and the second opening pattern includes at least one opening exposing the sub-pixel; and
a sidewall of the at least one opening is disposed further inward than a side surface of the diffusion layer.
